(19) United States
(12) Patent Application Publication
(10) Pub. No.: US 2025/0044686 A1
(43) Pub. Date: Feb. 6, 2025

(54) METHOD OF FORMING PATTERNS

(71) Applicant: SAMSUNG SDI CO., LTD., Yongin-si (KR)

(72) Inventors: Yaeun SEO, Suwon-si (KR); Jimin KIM, Suwon-si (KR); Minyoung LEE, Suwon-si (KR); Eunmi KANG, Suwon-si (KR); Taegeun SEONG, Suwon-si (KR); Changsoo WOO, Suwon-si (KR); Sumin JANG, Suwon-si (KR); Bukeun OH, Suwon-si (KR); Chungheon LEE, Suwon-si (KR)

(21) Appl. No.: 18/764,931

(22) Filed: Jul. 5, 2024

(30) Foreign Application Priority Data
Aug. 4, 2023 (KR) 10-2023-0102396

(51) Int. Cl. G03F 7/004; G03F 7/00; G03F 7/039

(52) U.S. Cl. CPC G03F 7/0045; G03F 7/039; G03F 7/70233

(57) ABSTRACT

Disclosed is a method of forming patterns including coating a metal-containing resist composition on a substrate; a heat treatment including drying and heating to form a metal-containing resist layer on the substrate; exposing a metal-containing resist layer using a patterned mask; and developing including coating a developer composition to remove unexposed regions to form a resist pattern, wherein the coating the metal-containing resist composition is performed by coating the metal-containing resist composition with a spin coater at a speed of about 100 to about 1,500 rpm for about 60 to about 120 seconds, the heating is performed at a temperature of about 90 to about 200° C. for about 30 to about 120 seconds, the exposing the metal-containing resist layer is performed by irradiating extreme ultraviolet light, light having a wavelength of about 5 nm to about 50 nm, or a combination thereof.

### CROSS-REFERENCE TO RELATED APPLICATION

This application claims priority to and the benefit of Korean Patent Application No. 10-2023-0102396 filed in the Korean Intellectual Property Office on Aug. 4, 2023, the entire content of which is hereby incorporated by reference.

### BACKGROUND

### 1. Field

Embodiments of this disclosure relate to a method of forming patterns using a semiconductor photoresist composition.

### 2. Description of the Related Art

EUV (extreme ultraviolet) lithography is paid attention to as one technology for manufacturing a next generation semiconductor device. EUV lithography is a pattern-forming technology using an EUV ray having a wavelength of about 13.5 nm as an exposure light source. Utilizing EUV lithography, an extremely fine pattern (e.g., less than or equal to about 20 nm) may be formed in an exposure process during a manufacture of a semiconductor device.

Extreme ultraviolet (EUV) lithography may be performed utilizing development of compatible photoresists which can be performed at a spatial resolution of less than or equal to about 16 nm. Currently, efforts to satisfy insufficient specifications of traditional chemically amplified (CA) photoresists such as a resolution, a photospeed, and feature roughness (which may also be referred to as a line edge roughness or LER) for next generation devices are being made.

An intrinsic image blurring due to an acid catalyzed reaction in these polymer-type photoresists limits a resolution in small feature sizes, which has been observed in electron beam (e-beam) lithography for a long time. Chemically amplified (CA) photoresists are designed for high sensitivity, but because their general elemental makeups reduce light absorbance of the photoresists at a wavelength of about 13.5 nm, and thus, decrease their sensitivity, chemically amplified (CA) photoresists may at least partially have more difficulties under an EUV exposure.

CA photoresists may have difficulties with respect to small feature sizes due to roughness issues, and line edge roughness (LER) of CA photoresists experimentally turns out to be increased, as a photospeed is decreased at least partially due to an essence of acid catalyst processes. Accordingly, an improved high-performance photoresist would be beneficial in a semiconductor industry because of these defects and problems of the CA photoresists.

To overcome the aforementioned drawbacks of chemically amplified (CA) organic photosensitive composition, an inorganic photosensitive composition has been researched. Inorganic photosensitive compositions are mainly used for negative tone patterning having resistance against removal by a developer composition due to chemical modification through a nonchemical amplification mechanism. Inorganic photosensitive compositions contain an inorganic element having a higher EUV absorption rate than hydrocarbons, and thus, may secure sensitivity through a nonchemical amplification mechanism and are less sensitive with respect to a stochastic effect, and thus, have low line edge roughness and small numbers of defects.

Inorganic photoresists based on peroxopolyacids of tungsten mixed together with tungsten, niobium, titanium, and/or tantalum have been observed as radiation sensitive materials for patterning.

These materials are effective for patterning large pitches for bilayer configuration by utilizing far ultraviolet (deep UV), X-ray, and electron beam sources.

More recently, when cationic hafnium metal oxide sulfate (HfSOx) materials along with a peroxo complexing agent have been used to image a 15 nm half-pitch (HP) through projection EUV exposure, impressive performance has been obtained. This system exhibits the highest performance of a non-CA photoresist and has a practicable photospeed near to a useful range for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of about 25 wt % and/or the like.

Recently, active research has been conducted with respect to molecules containing tin that have excellent absorption of extreme ultraviolet rays. As for an organotin polymer among them, alkyl ligands are dissociated by light absorption or secondary electrons produced thereby, and are crosslinked with adjacent chains through oxo bonds, and thus, enable negative tone patterning which may not be removed by an organic developer. This organotin polymer exhibits greatly improved sensitivity as well as maintains a resolution and line edge roughness, but the patterning characteristics should be further improved for commercial availability.

### SUMMARY

Some embodiments of the present disclosure provide a method of forming patterns using the semiconductor photoresist composition, and can achieve excellent resolution.

A method of forming patterns according to some embodiments includes coating a metal-containing resist composition on a substrate; a heat treatment including drying and heating to form a metal-containing resist layer on the substrate; exposing a metal-containing resist layer using a patterned mask; and developing including coating a developer composition to remove unexposed regions to form a resist pattern,
wherein the coating the metal-containing resist composition is performed by coating the metal-containing resist composition with a spin coater at a speed of about 100 to about 1,500 rpm for about 60 to about 120 seconds, the heating is performed at a temperature of about 90 to about 200° C. for about 30 to about 120 seconds, and the exposing the metal-containing resist layer is performed by irradiating extreme ultraviolet light, light having a wavelength of about 5 nm to about 50 nm, or a combination thereof,
a surface roughness of the metal-containing resist layer that has undergone the heat treatment step has a root mean square roughness (R_{q}) of more than or equal to about 1.5 nm, an average roughness (Rₐ) of less than or equal to about 1.0 nm, and a maximum roughness (Rₘₐₓ: peak to peak height) of less than or equal to about 20 nm.

The root mean square roughness (R_{q}) may be about 0.1 nm to about 1.5 nm.

The average roughness (Rₐ) may be about 0.1 nm to about 1.0 nm.

The maximum roughness (Rₘₐₓ) may be about 1 nm to about 20 nm.

The metal compound included in the metal-containing resist composition may include at least one selected from an organooxy group-containing tin compound and an organocarbonyloxy group-containing tin compound.

The metal compound included in the metal-containing resist composition may be represented by Chemical Formula 1.

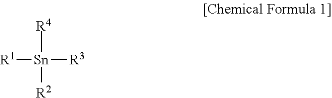

In Chemical Formula 1,

R¹ to R⁴ are each selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, substituted or unsubstituted C6 to C30 aryl group, a substituted or unsubstituted C7 to C30 arylalkyl group, —OR^{b} and —OC(═O)R^{c},
at least one selected from R² to R⁴ are each independently selected from —OR^{b} and —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

R¹ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, —OR^{b} or —OC(═O)R^{c}.

R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof.

The metal compound may be included in an amount of about 1 wt % to about 30 wt % based on 100 wt % of the metal-containing resist composition.

The metal-containing resist composition may further include additives such as a surfactant, a crosslinking agent, a leveling agent, an organic acid, a quencher, or a combination thereof.

The method may further include providing a resist underlayer formed between the substrate and the metal-containing resist layer.

The photoresist pattern may have a width of about 5 nm to about 100 nm.

A resist pattern manufactured using the method of forming patterns according to some embodiments can implement excellent resolution.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-5 are cross-sectional views for explaining a method of forming patterns using a metal-containing resist composition according to some embodiments.

FIGS. 6 to 13 are SEM photographs of resist thin films according to Examples and Comparative Examples.

### DETAILED DESCRIPTION

Hereinafter, referring to the drawings, embodiments of the present disclosure are described in more detail. In the following description of the subject matter of the present disclosure, well-known functions and/or constructions will not be described in order to clarify the subject matter of the present disclosure.

In order to clearly illustrate the subject matter of the present disclosure, certain description and/or relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, etc., may be enlarged for clarity. In the drawings, the thickness of a part of layers or regions, etc., may be exaggerated for clarity. It will be understood that if an element such as a layer, film, region, or substrate is referred to as being “on” another element, it can be directly on the other element or intervening elements may also be present.

As used herein, the term “substituted” refers to replacement of a hydrogen atom by deuterium, a halogen, a hydroxy group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if a definition is not otherwise provided, the term “an alkyl group” refers to a linear or branched aliphatic hydrocarbon group. The alkyl group may be “a saturated alkyl group” without any double bond or triple bond.

The alkyl group may be a C1 to C10 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if a definition is not otherwise provided, the term “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As used herein, the term “aryl group” refers to a substituent in which all atoms in the cyclic substituent have a p-orbital and these p-orbitals are conjugated and may include a monocyclic or fused ring polycyclic (e.g., rings sharing adjacent pairs of carbon atoms) functional group.

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

In the Chemical Formulas described herein, t-Bu refers to a tert-butyl group.

Hereinafter, a method of forming patterns according to some embodiments is described in more detail.

A method of forming patterns according to some embodiments of the present disclosure includes coating a metal-containing resist composition on a substrate; a heat treatment including drying and heating to form a metal-containing resist layer on the substrate; exposing a metal-containing resist layer using a patterned mask; and a developing including coating a developer composition to remove unexposed regions to form a resist pattern,
wherein the coating the metal-containing resist composition is performed by coating the metal-containing resist composition with a spin coater at a speed of about 100 to about 1,500 rpm for about 60 to about 120 seconds, the heating is performed at a temperature of about 90 to about 200° C. for about 30 to about 120 seconds, and the exposing the metal-containing resist layer is performed by irradiating extreme ultraviolet light, light having a wavelength of about 5 nm to about 50 nm, or a combination thereof,
a surface roughness of the metal-containing resist layer that has undergone the heat treatment step has a root mean square roughness (R_{q}) of more than or equal to about 1.5 nm, an average roughness (Rₐ) of less than or equal to about 1.0 nm, and a maximum roughness (Rₘₐₓ: peak to peak height) of less than or equal to about 20 nm.

The method of forming patterns according to embodiments of the present disclosure is a method of forming a film and patterning it if a metal-containing resist composition including a metal compound containing a metal, such as tin, an additive, and a solvent is applied to the surface of a substrate. The resist layer formed of the metal-containing resist composition may be checked with respect to surface roughness through an AFM (Atomic Force Microscope) analysis, wherein Rq of less than or equal to about 1.5 nm, Ra of less than or equal to about 1.0 nm, and Rmax of less than or equal to 20 nm may confirm excellent resolution in a photoresist process.

The surface roughness is measured by taking an image of the metal-containing resist with an atomic force microscope (AFM) and/or the like, for example, an optical profiler.

In the surface roughness, the root mean square roughness (R_{q}) may mean a root average square (rms) of a vertical value within a reference length of a roughness profile. The average roughness (Rₐ) is also referred to as a center line average roughness and may mean an arithmetic average of an absolute value of the vertical value (ordinate; a length from the center line to a peak) within the reference length of the roughness profile. The maximum roughness (Rₘₐₓ; a peak to a peak height; a maximum roughness depth) may mean a vertical distance between the highest peak and the deepest peak (lowest valley) within the reference length of a roughness cross-section curve (the roughness profile). This surface roughness may be obtained by referring to parameter definitions and measurement methods defined in KS B 0601 or ISO 4287/1.

The root mean square roughness (R_{q}) may be about 0.1 nm to about 1.5 nm.

For example, the root mean square roughness (R_{q}) may be about 0.2 nm to about 1.5 nm, for example, about 0.3 nm to about 1.5 nm, about 0.4 nm to about 1.5 nm, or about 0.5 nm to about 1.5 nm.

In some embodiments, the root mean square roughness (R_{q}) may be about 0.5 nm to about 1.4 nm.

The average roughness (Rₐ) may be about 0.1 nm to about 1.0 nm.

For example, the average roughness (Rₐ) may be about 0.2 nm to about 1.0 nm, such as about 0.3 nm to about 1.0 nm, about 0.4 nm to about 1.0 nm, or about 0.5 nm to about 1.0 nm.

In some embodiments, the average roughness (Rₐ) may be about 0.5 nm to about 0.9 nm.

The maximum roughness (Rₘₐₓ) may be about 1 nm to about 20 nm.

For example, the maximum roughness (Rₘₐₓ) may be about 1 nm to about 20 nm, such as about 2 nm to about 20 nm, about 3 nm to about 20 nm, or about 4 nm to about 20 nm.

In some embodiments, the maximum roughness (Rₘₐₓ) may be about 5 nm to about 20 nm.

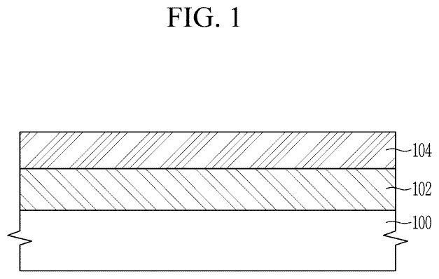

Hereinafter, the method of forming a pattern will be described with reference to FIGS. 1-5. FIGS. 1-5 are cross-sectional views illustrating a method of forming patterns using the metal-containing resist composition according to some embodiments.

1 Referring to FIG. 1, an object for etching is prepared. The object for etching may be a thin film 102 on a semiconductor substrate 100. Hereinafter, the object for etching is limited to the thin film 102, but the present disclosure is not limited thereto. A whole surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, the embodiment is not limited thereto, and various suitable coating methods, for example a spray coating, a dip coating, a knife edge coating, a printing method, for example an inkjet printing and/or a screen printing, and/or the like may be used.

The coating process of the resist underlayer may be omitted, and hereinafter, a process including a coating of the resist underlayer is described.

The coated composition is dried and baked to form a resist underlayer 104 on the thin film 102. The baking may be performed at about 100° C. to about 500° C., or, for example, about 100° C. to about 300° C.

The resist underlayer 104 is formed between the substrate 100 and a photoresist layer 106, and thus, may prevent or reduce non-uniformity and prevent or reduce a decrease in pattern formability of a photoresist line width if a ray reflected from on the interface between the substrate 100 and the photoresist layer 106 or a hardmask between layers is scattered into an unintended photoresist region.

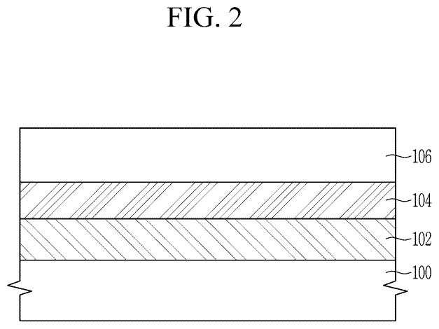

Referring to FIG. 2, the photoresist layer 106 is formed by coating the metal-containing resist composition on the resist underlayer 104. The photoresist layer 106 is obtained by coating the aforementioned metal-containing resist composition on the thin film 102 formed on the substrate 100 and then, curing it through a heat treatment.

In embodiments, the formation of a pattern by using the metal-containing resist composition may include coating the metal-containing resist composition on the substrate 100 having the thin film 102 through spin coating, slit coating, inkjet printing, and/or the like and then, drying it to form the photoresist layer 106.

The metal-containing resist composition may include a tin-based compound, and, for example, the tin-based compound may include at least one selected from an organooxy group-containing tin compound and an organocarbonyloxy group-containing tin compound.

As an example, the metal compound included in the metal-containing resist composition may be represented by Chemical Formula 1.

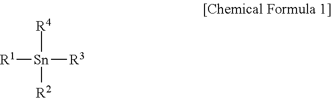

In Chemical Formula 1,

R¹ to R⁴ are each selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{b} and —OC(═O)R^{c},
at least one selected from R² to R⁴ are each independently selected from —OR^{b} and —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

For example, R¹ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, —OR^{b} or —OC(═O)R^{c}.

For example, R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof.

For example, R^{b} and R^{c} may each independently be a substituted or unsubstituted C1 to C20 alkyl group.

Subsequently, a heat treatment including heating the substrate 100 on which the photoresist layer 106 is formed is performed. The heating may be performed at a temperature of about 90° C. to about 200° C. for about 30 to about 120 seconds.

In the metal-containing resist composition according to some embodiments, based on 100 wt % of the metal-containing resist composition, the metal-containing compound may be included in an amount of about 1 wt % to about 30 wt %, for example, about 1 wt % to about 25 wt %, for example, about 1 wt % to about 20 wt %, for example, about 1 wt % to 15 wt %, for example, about 1 wt % to 10 wt %, or, for example, about 1 wt % to about 5 wt %, but is not limited thereto.

The metal-containing resist composition according to some embodiments may include a solvent. The solvent may be an organic solvent, and may be, for example, aromatic compounds (e.g., xylene, toluene, etc.), alcohols (e.g., 4-methyl-2-pentenol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but is not limited thereto.

The metal-containing resist composition according to some embodiments may further include a resin in addition to the aforementioned organometallic compound, vinyl group-containing acid compound, and solvent.

The resin may be a phenolic resin including at least one aromatic moiety of Group 1.

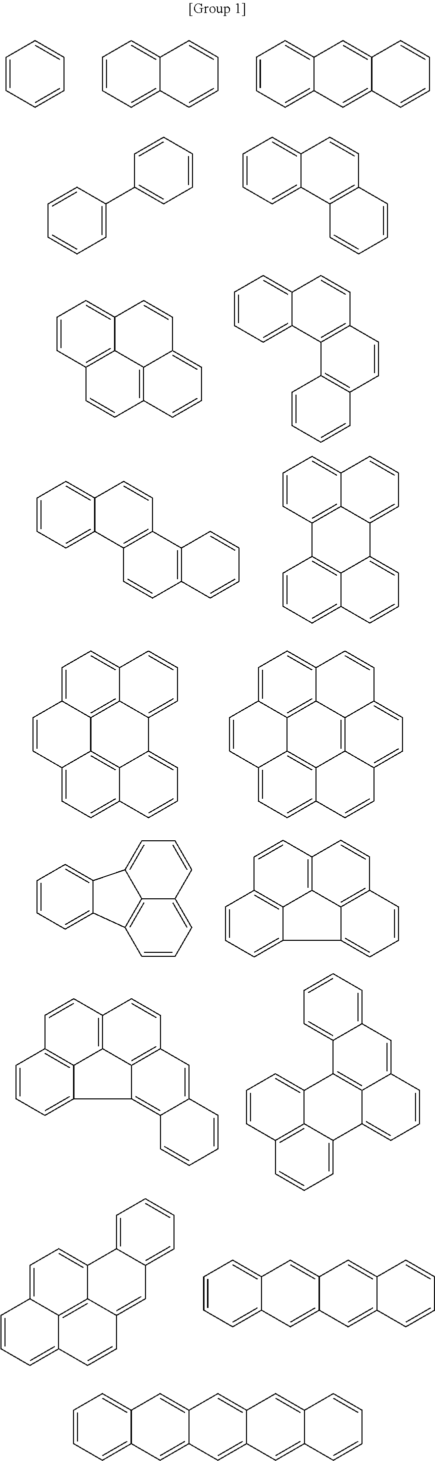

The resin may have a weight average molecular weight of about 500 to about 20,000.

The resin may be included in an amount of about 0.1 wt % to about 50 wt % based on the total amount of the semiconductor photoresist composition.

If the resin is included in the above content range, it may have excellent etch resistance and heat resistance.

1 The metal-containing resist composition according to some embodiments may consist of the aforementioned organometallic compound, solvent, and resin. However, the metal-containing resist composition according to the embodiment may further include additives as needed or desired. Examples of the additives may be a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but is not limited thereto. The crosslinking agent may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis (glycidoxypropyl)tetramethyldisiloxane, methoxymethylated urea, butoxymethylated urea, and/or methoxymethylated thiourea, and/or the like.

The leveling agent may be used for improving coating flatness during printing and may be any suitable leveling agent generally used in the art.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl(p-tolyl)amine, methyl diphenyl amine, triphenyl amine, phenylenediamine, naphthylamine, diaminonaphthalene, or a combination thereof.

A use amount of the additives may be controlled depending on suitable or desired properties.

In embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(β-methoxyethoxy) silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino) propyl]silane, and/or the like, but is not limited thereto.

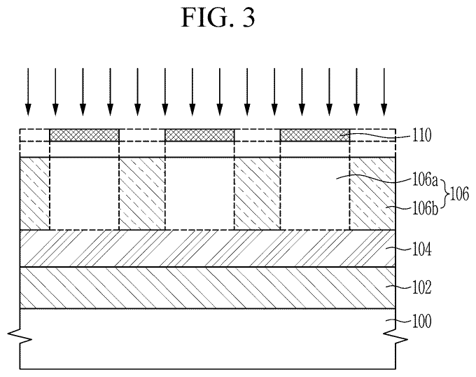

Referring to FIG. 3, the photoresist layer 106 may be selectively exposed using a patterned mask 110.

For example, the exposure may use an activation radiation including light having a high energy wavelength such as a short wavelength in a range from about 5 nm to about 150 nm and a high energy wavelength, for example, EUV (extreme ultraviolet; a wavelength of 13.5 nm), an E-Beam (an electron beam), and/or the like.

An exposed region 106b of the photoresist layer 106 has a different solubility from an unexposed region 106a of the photoresist layer 106 by forming a polymer by a crosslinking reaction such as, for example, a condensation reaction between organometallic compounds.

Subsequently, the substrate 100 is subjected to a second baking process. The baking process may be performed at a temperature of about 90° C. to about 200 1° C. The exposed region 106b of the photoresist layer 106 becomes easily indissoluble with respect to a developer due to the baking process.

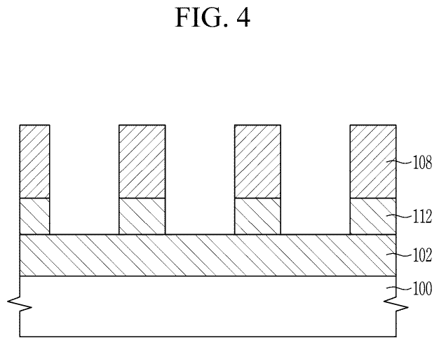

In FIG. 4, the unexposed region 106a of the photoresist layer is dissolved and removed using the developer to form a photoresist pattern 108. In embodiments, the unexposed region 106a of the photoresist layer is dissolved and removed by using an organic solvent such as 2-heptanone and/or the like to complete the photoresist pattern 108 corresponding to the negative tone image.

As described above, a developer used in a method of forming patterns according to some embodiments may be an organic solvent. The organic solvent used in the method of forming patterns according to some embodiments may be, for example, ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of about 5 nm to about 100 nm. For example, the photoresist pattern 108 may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In embodiments, the photoresist pattern 108 may have a pitch of having a half-pitch of less than or equal to about 50 nm, for example, less than or equal to about 40 nm, for example, less than or equal to about 30 nm, for example, less than or equal to about 20 nm, or, for example, less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

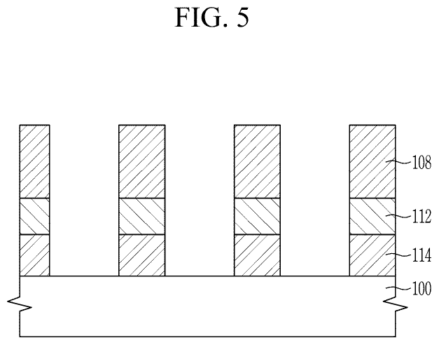

Referring to FIG. 5, the exposed thin film 102 is etched by applying the photoresist pattern 108 as an etching mask. As a result, the thin film is formed as a thin film pattern 114.

The etching of the thin film 102 may be, for example, dry etching using an etching gas and the etching gas may be, for example, CHF₃, CF₄, Cl₂, BCl₃, and/or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of 5 nm to 100 nm, which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, or, for example, a width of less than or equal to about 20 nm, like that of the photoresist pattern 108.

Hereinafter, embodiments of the present disclosure will be described in more detail through examples of the preparation of the aforementioned semiconductor photoresist composition. However, the present disclosure is technically not restricted by the following examples.

### Synthesis of Metal-containing Organic Compounds

### Synthesis Example 1

An organic tin compound represented by Chemical Formula A (10 g, 25.5 mmol) was dissolved in 30 ml of anhydrous toluene, and 6.0 g of propionic acid was slowly added thereto in a dropwise fashion and then, stirred at 0° C. for 6 hours. Subsequently, after increasing the temperature to room temperature (23° C.) and removing the toluene therefrom by vacuum distillation, the resultant residual filtrate was subjected to fractional distillation to obtain an organic tin compound represented by Chemical Formula 2.

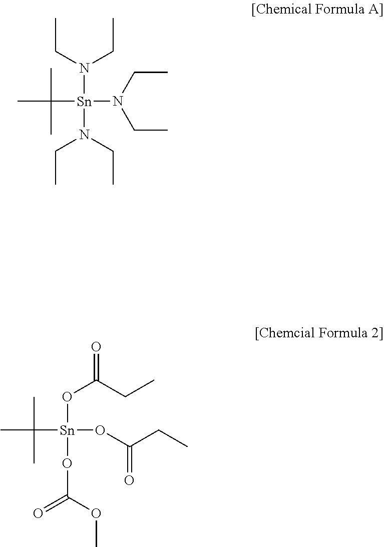

### Synthesis Example 2

An organic tin compound represented by Chemical Formula B (10 g, 27.3 mmol) was dissolved in 30 ml of anhydrous toluene, and 6.2 g of propionic acid was slowly added thereto in a dropwise fashion and then, stirred at 0° C. for 6 hours. Subsequently, after increasing the temperature to room temperature and then, removing the toluene therefrom by vacuum distillation, the resultant residual filtrate was subjected to fractional distillation to obtain an organic tin compound represented by Chemical Formula 3.

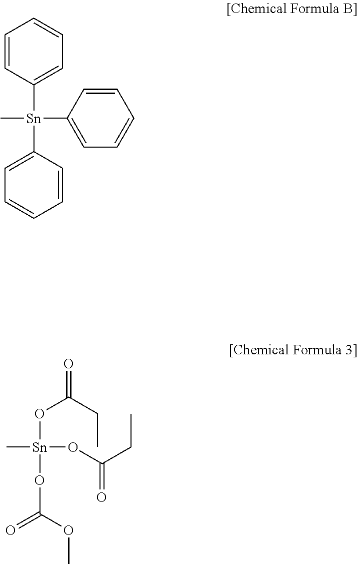 [SMILES: [CH3][Sn]([c]1ccccc1)([c]1ccccc1)[c]1ccccc1 ; CCC(=O)[O][Sn]([CH3])([O]C(=O)CC)[O]C(=O)OC]

### Synthesis Example 3

An organic tin compound represented by Chemical Formula C (10 g, 31.0 mmol) was dissolved in 30 ml of anhydrous toluene, and 7.0 g of propionic acid was slowly added thereto in a dropwise fashion and then, stirred at 0° C. for 6 hours. Subsequently, after increasing the temperature to room temperature and then, removing the toluene therefrom by vacuum distillation, the resultant residual filtrate was subjected to fractional distillation to obtain an organic tin compound represented by Chemical Formula 4.

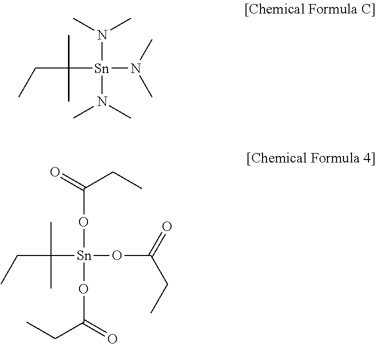

### Preparation of Semiconductor Photoresist Compositions

### Examples 1 to 7 and Comparative Examples 1 and 2

The compounds and additives represented by Chemical Formula 2 to Chemical Formula 4 obtained in Synthesis Examples 1 to 3 were respectively dissolved in 1-methoxy-2-propyl acetate in the compositions shown in Table 1, and then filtered through a 0.1 μm PTFE syringe filter to prepare respective photoresist compositions.

An 8-inch diameter circular silicon wafer with a native-oxide surface was used as a substrate for thin film deposition. The resist composition was spin-coated on the wafer at 1500 rpm for 60 seconds, and baked at 110° C. for 60 seconds to form a thin film. Then, the thickness of the film after coating and firing was measured through ellipsometry and was found to be about 25 nm for Examples 1 to 6, and about 24 nm for Comparative Examples 1 and 2.

TABLE 1

| | Organometallic compound | Additive | Solvent |
|---|---|---|---|
| | (wt %) | (wt %) | (wt %) |
| Example 1 | Chemical Formula 2 (0.9), | — | (99) |
| | Chemical Formula 3 (0.1) | | |
| Example 2 | Chemical Formula 2 (0.9), | Additive 1 (0.1) | (98.9) |
| | Chemical Formula 3 (0.1) | | |
| Example 3 | Chemical Formula 2 (0.9), | Additive 2 (1) | (98) |
| | Chemical Formula 3 (0.1) | | |
| Example 4 | Chemical Formula 2 (0.9), | Additive 2 (2) | (97) |
| | Chemical Formula 3 (0.1) | | |
| Example 5 | Chemical Formula 4 (1) | — | (99) |
| Example 6 | Chemical Formula 4 (1) | Additive 3 (0.1) | (98.9) |
| Comparative | Chemical Formula 2 (1) | — | (99) |
| Example 1 | | | |
| Comparative | Chemical Formula 2 (1) | Additive 1 (0.05) | (98.9) |
| Example 2 | | Additive 4 (0.05) | |

* Additive 1: Propionic acid (TCI)
* Additive 2: Admantanecarboxylic acid (Sigma Aldrich)
* Additive 3: Glycolic acid (Daejung Chemicals Co., Ltd.)
* Additive 4: 1-Methylcyclohexanecarboxylic acid (Sigma Aldrich)

### Evaluation 1: Surface Roughness

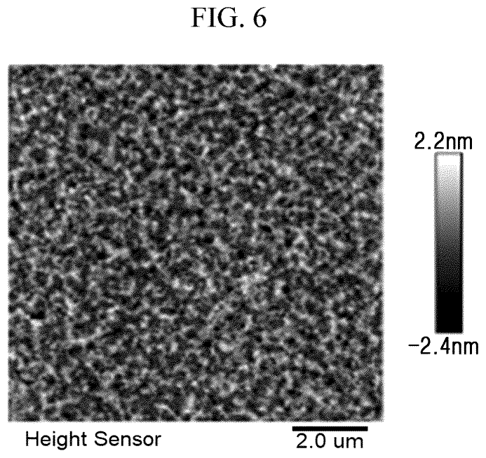

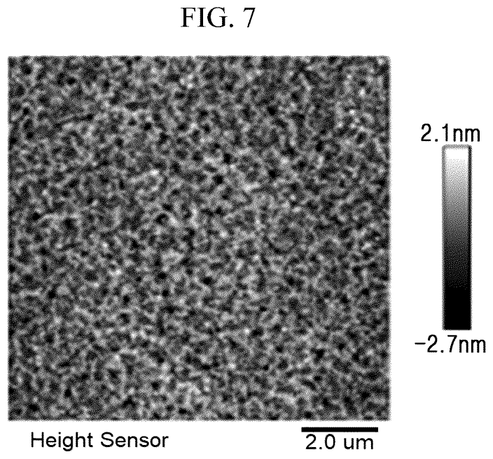

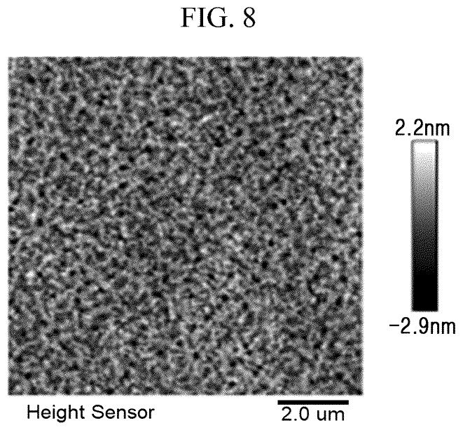

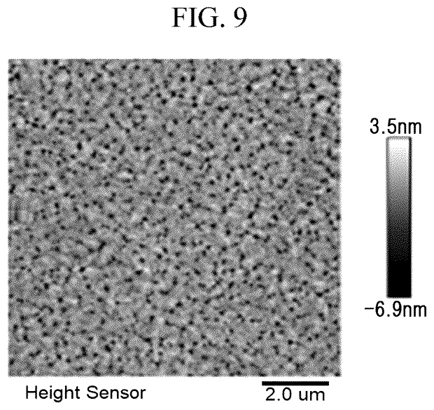

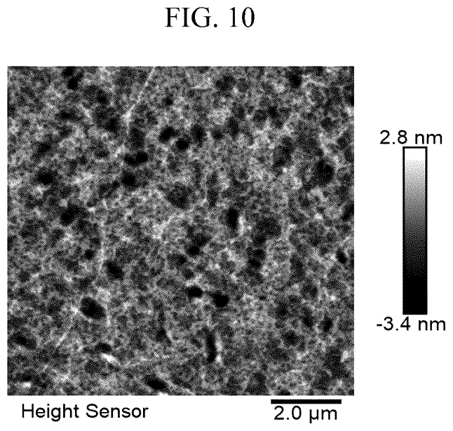

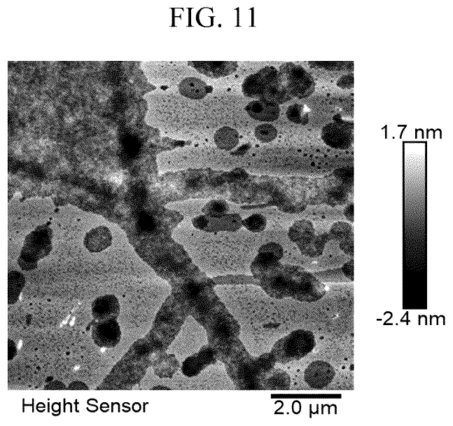

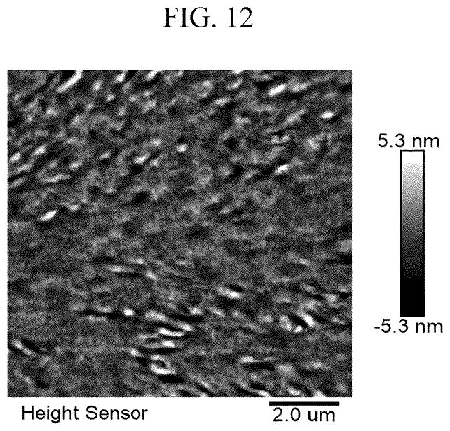

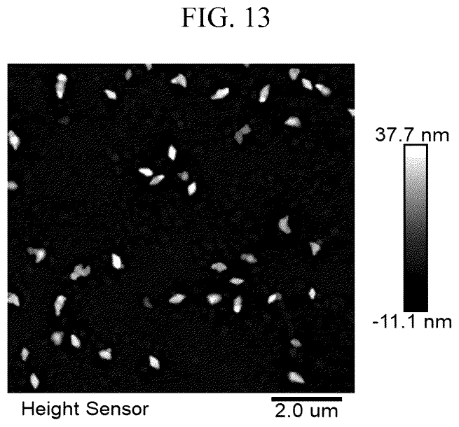

Each of the resist compositions according to Examples 1 to 6 and Comparative Examples 1 and 2 was spin-coated on a wafer at 1500 rpm for 60 seconds and baked at 110° C. for 60 seconds to form thin films, and after taking an image of the thin films with a scanning electron microscope, the image results are shown in FIGS. 6 to 13, from which surface roughness of the thin films is measured by using a software, and the results are shown in Table 1.

### Evaluation 2: Pattern Formability

A linear array of 50 circular pads each having a diameter of 500 μm was projected onto a wafer coated with each of the composition for a photoresist according to Examples 1 to 6 and Comparative Examples 1 and 2 by using EUV light (Lawrence Berkeley National Laboratory Micro Exposure Tool, MET). Herein, pad exposure time was adjusted to apply an increased EUV dose per each pad.

Subsequently, the resist and the substrate were exposed at 160° C. on a hotplate for 120 second and then, baked (post-exposure baked, PEB). The baked films were dipped in a developing solution (2-heptanone) for 30 seconds and additionally washed with the same developer for 10 seconds to form a negative tone image, that is, to remove a non-exposed coating region. Finally, the films were further baked at 150° C. on the hotplate baking for 2 minutes, thereby completing a process.

After completing the process, whether or not a L/S pattern was formed was examined with a microscope, and the results are shown in Table 2.

TABLE 2

| | AFM | | | Pattern |
|---|---|---|---|---|
| | R_{q} | Rₐ | Rₘₐₓ | Formability |
| Example 1 | 0.89 | 0.64 | 13.26 | Good |
| Example 2 | 0.89 | 0.63 | 13.55 | Good |
| Example 3 | 0.82 | 0.59 | 12.32 | Good |
| Example 4 | 1.38 | 0.89 | 18.30 | Good |
| Example 5 | 0.84 | 0.66 | 8.76 | Good |
| Example 6 | 0.59 | 0.47 | 7.2 | Good |
| Comparative Example 1 | 1.54 | 1.12 | 20.35 | Inferior |
| Comparative Example 2 | 5.1 | 2.16 | 57.1 | Pattern cannot be formed |

Referring to the results of Table 2, the patterns formed according to the method of forming patterns according to the examples exhibited excellent resolution.

Hereinbefore, certain embodiments of the present disclosure have been described and illustrated, however, it is apparent to a person with ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the appended claims of the present disclosure, and equivalents thereof.

<Description of Symbols>

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A method of forming patterns, comprising:
coating a metal-containing resist composition on a substrate;
drying and heating to form a metal-containing resist layer on the substrate;
exposing the metal-containing resist layer using a patterned mask; and
coating a developer composition to remove unexposed regions to form a resist pattern,
wherein the coating of the metal-containing resist composition is performed by coating the metal-containing resist composition with a spin coater at a speed of about 100 to about 1,500 rpm for about 60 to about 120 seconds,
the heating is performed at a temperature of about 90 to about 200° C. for about 30 to about 120 seconds,
the exposing of the metal-containing resist layer is performed by irradiating extreme ultraviolet light, light having a wavelength of about 5 nm to about 50 nm, or a combination thereof,
a surface roughness of the metal-containing resist layer that has undergone the heating has a root mean square roughness (R_{q}) of more than or equal to about 1.5 nm, an average roughness (Rₐ) of less than or equal to about 1.0 nm, and a maximum roughness (Rₘₐₓ: peak to peak height) of less than or equal to about 20 nm.

2. The method as claimed in claim 1, wherein:
the root mean square roughness (R_{q}) is about 0.1 nm to about 1.5 nm.

3. The method as claimed in claim 1, wherein:
the average roughness (Rₐ) is about 0.1 nm to about 1.0 nm.

4. The method as claimed in claim 1, wherein:
1 the maximum roughness (Rₘₐₓ) is about 1 nm to about 20 nm.

5. The method as claimed in claim 1, wherein:
a metal compound included in the metal-containing resist composition comprises at least one selected from an organooxy group-containing tin compound and an organocarbonyloxy group-containing tin compound.

6. The method as claimed in claim 1, wherein:
a metal compound included in the metal-containing resist composition is represented by Chemical Formula 1: 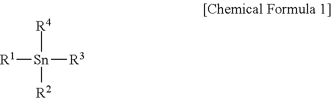
wherein, in Chemical Formula 1,
R¹ to R⁴ are each selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{b} and —OC(═O)R^{c},
at least one selected from R² to R⁴ are each independently selected from —OR^{b} and —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

7. The method as claimed in claim 1, wherein:
R¹ is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, —OR^{b} or —OC(═O)R^{c}.

8. The method as claimed in claim 1, wherein:
R¹ is a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof.

9. The method as claimed in claim 1, wherein:
a metal compound is included in an amount of about 1 wt % to about 30 wt % based on 100 wt % of the metal-containing resist composition.

10. The method as claimed in claim 1, wherein:
the metal-containing resist composition further comprises an additive of a surfactant, a crosslinking agent, a leveling agent, an organic acid, a quencher, or a combination thereof.

11. The method as claimed in claim 1, wherein:
the method further comprises providing a resist underlayer formed between the substrate and the metal-containing resist layer.

12. The method as claimed in claim 1, wherein:
the resist pattern has a width of about 5 nm to about 100 nm.
